(19) United States
(12) Patent Application Publication
(10) Pub. No.: US 2007/0065598 A1
(43) Pub. Date: Mar. 22, 2007

(54) Plasma processing device

(76) Inventor: Roger-Michael Wolf, Dresden (DE)

Correspondence Address: SLATER & MATSIL LLP, 17950 PRESTON ROAD, SUITE 1000, DALLAS, TX, 75252, US

(21) Appl. No.: 11/525,543

(22) Filed: Sep. 22, 2006

(30) Foreign Application Priority Data
Sep. 22, 2005 (DE) 10 2005 046 463.7

(51) Int. Cl. H05H 1/24; C23C 16/00

(52) U.S. Cl. 427/569; 118/723 R

(57) ABSTRACT

A plasma processing device includes at least one process chamber for receiving an article, for example a wafer, that is to be processed using a plasma. The process chamber has a prescribed chamber construction. A flow-influencing apparatus is arranged in the process chamber and set in such a manner that an asymmetrical inner space is produced within the process chamber thereby changing a flow behavior of a process gas contained in the process chamber.

This application claims priority to German Patent Application 10 2005 046 463.7, which was filed Sep. 22, 2005 and is incorporated herein by reference.

### TECHNICAL FIELD

The invention relates generally to a plasma processing device.

### BACKGROUND

A plasma processing device has at least one process chamber for receiving an article, in particular a wafer, which to be processed, the process chamber having a prescribed chamber construction. Within the process chamber, the article to be processed is processed using the plasma of the plasma processing device, while a process gas flows through the process chamber. To this end, components for forming plasma and for generating a process gas stream are provided inside and/or outside the process chamber.

Such plasma processing devices are generally known and are used, for example, as plasma etching installations for plasma-etching wafers or as plasma coating installations for coating wafers (for example during CVD (Chemical Vapor Deposition) methods) or for carrying out thermal processes (for example oxidation, nitridation or annealing).

In order to achieve particularly high uniformity when processing the article to be processed, in order to ensure a uniform etching rate over the entire area of a wafer, for example, very great efforts are made to achieve a construction of the process chamber that is as symmetrical as possible. This procedure is based on the idea that a symmetrical construction of the process chamber results in a rotationally symmetrical process gas stream behavior within the process chamber, thus achieving a particularly high degree of uniformity in the processing behavior even over relatively large wafer areas.

### SUMMARY OF THE INVENTION

Starting from a plasma processing device of the type specified initially, advantages can be achieved, according to embodiments of the invention, by virtue of the fact that flow-influencing means that can be additionally set are arranged in the process chamber and can be set in such a manner that they produce an asymmetrical inner space within the process chamber and thus change the flow behavior of the process gas contained in the process chamber.

A considerable advantage of the plasma processing device according to one embodiment of the invention can be seen in the fact that, in said device, an “asymmetrical” change in the inner space of the process chamber can be used to change the flow conditions in the latter in a very specific manner. For example, the asymmetry added according to the invention can be used, on the one hand, to ensure that a wafer which has already been processed asymmetrically (for example a wafer which has been processed in a distorted manner in a preceding etching or coating step) subsequently becomes symmetrical again; furthermore, wafers which have been deliberately processed asymmetrically can be fabricated and opposite asymmetrical processing steps which subsequently take place can thus be compensated for. On the other hand, asymmetry which is additionally added can be used to compensate for chamber-dictated asymmetry which is present in the process chamber in an undesirable manner. Despite a largely ideal symmetrical construction of a process chamber, it is thus not possible to completely avoid remaining asymmetry occurring in the flow behavior of the process gas within the process chamber, as was found by the inventors. The invention begins at this point by making provision for flow-influencing means, which can be set, to be used to deliberately cause structural asymmetry in the process chamber and thus to provide a type of “counter-asymmetry” which is used, in the end result, to achieve a desired processing behavior of the plasma processing device, for example a symmetrical processing behavior as a result of a symmetrical plasma distribution within the process chamber. In combination with non-uniform upstream or downstream processes, it is thus possible to use deliberately non-uniform (but opposite) processes to achieve an overall process result which is more uniform overall.

### BRIEF DESCRIPTION OF THE DRAWINGS

The invention will be explained in more detail below with reference to exemplary embodiments. In the drawings

FIGS. 1 and 2 show a cross-section and a plan view of a plasma processing device according to the prior art;

FIGS. 3 and 4 show a first exemplary embodiment of a plasma processing device according to the invention, in which flow-influencing means are fitted on the “liner” side;

FIGS. 5, 6, 6a, and 7 show a second exemplary embodiment of a plasma processing device according to the invention, in which flow-influencing means are arranged laterally beside a retaining element of the plasma processing device;

FIG. 8 shows a third exemplary embodiment of a plasma processing device according to the invention, in which flow-influencing means have a contour which is specially adapted to the contour of the retaining element of the plasma processing device;

FIG. 9 shows a fourth exemplary embodiment of a plasma processing device according to the invention, in which flow-influencing means are fitted both on the liner side and in the region of the retaining element;

FIGS. 10aand 10bshow a side view of a fifth exemplary embodiment of a plasma processing device according to the invention, in which flow-influencing means are fitted in the upper region of the retaining element and are shown once in a raised position and once in a lowered position; and

FIGS. 11a and 11b show plan views of the plasma processing device according to the invention as shown in FIGS. 10aand 10b.

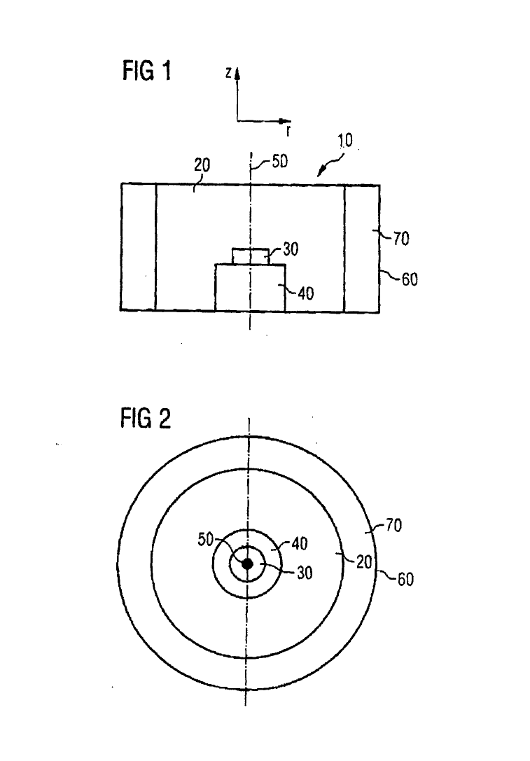

For the purpose of better clarity and for the purpose of better understanding, the same reference symbols are used for identical or comparable elements in FIGS. 1 to 11b.

### DETAILED DESCRIPTION OF ILLUSTRATIVE EMBODIMENTS

The process chamber as such preferably has a symmetrical, particularly preferably rotationally symmetrical, construction. In this case, asymmetry within the process chamber is exclusively, at least essentially, produced by the flow-influencing means according to the invention.

The inside of process chambers are usually lined with a liner in order to avoid the process gas damaging the inner wall of the process chamber or to avoid the process gas being contaminated with materials from the wall of the process chamber. If such a liner is present, it is regarded as being advantageous if the flow-influencing means are arranged in the region of the liner. For example, the liner has a recess or a passage opening in which the flow-influencing means are mounted.

Alternatively or additionally, the flow-influencing means may also be arranged in such a manner that they directly laterally adjoin a retaining element (for example, a cathode in combination with an electrostatic chuck) that is used to retain the article to be processed in the process chamber.

The flow-influencing means preferably have at least one diverter element which can be adjusted using a drive. The diverter element may be formed, for example, by a diverter plate or the like. The diverter element preferably has a cross-sectional area in the shape of a sickle or crescent. The drive for the flow-influencing means may be, for example, pneumatic or electromechanical and may comprise a bimetal element, a piezoelectric element or an electroactive polymer. The drive can preferably be adjusted continuously or in a plurality of stages.

Another advantageous refinement of the plasma processing device provides for the flow-influencing means to have at least one element that changes the cross-section, is arranged in the vicinity of at least one gas inlet opening and/or at least one gas outlet opening and can be used to asymmetrically adjust the cross-section of the gas inlet opening or the cross-section of the gas outlet opening. In the case of a plurality of gas inlet or gas outlet openings, the cross-section of different ones of these openings may be adjusted or closed separately, for example, so that an asymmetrical gas stream behavior is established overall.

Embodiments of the invention also relate to a method for processing an article using a plasma processing device, the article being introduced into a process chamber of the plasma processing device and being processed using a process gas in the process chamber.

In order to achieve particularly high uniformity in the processing behavior in the case of such a method, the invention proposes using flow-influencing means that are provided in the process chamber to produce an asymmetrical inner space within the process chamber and thus to change the flow behavior of the process gas contained in, for example, flowing through, the process chamber.

Regarding the advantages of the method according to the invention, reference is made to the statements made above in connection with the plasma processing device according to the invention since the advantages essentially correspond to one another. Advantageous refinements of the method according to the invention are specified in subclaims.

FIG. 1 shows a conventional plasma processing device 10. The plasma processing device 10 may be, for example, a plasma etching device or a plasma coating device. The plasma processing device 10 has a process chamber 20, for example a plasma etching chamber, into which an article 30 to be processed is introduced for the purpose of processing. The article 30 to be processed may be, for example, a wafer.

As can be seen in FIG. 1, the wafer 30 is fastened to a retaining element 40. The retaining element 40 is, for example, an electrostatic “chuck” that retains and cools the wafer 30 and operates as an electrode of the process chamber 20. Electrostatic chucks of this type are generally known in plasma processing devices.

As can also be seen in FIG. 1, the construction of the process chamber 20 is rotationally symmetrical; the rotational symmetry is symbolized in FIG. 1 by means of an axis of symmetry 50.

In order to avoid sidewalls 60 of the process chamber 20 being attacked by a plasma, for example an etching gas plasma, which is present in the process chamber 20 during processing of the wafer 30, the sidewall 60 is preferably lined with a tubular element in the form of a liner 70, however, the use of a liner is not absolutely necessary.

FIG. 2 again illustrates the plasma processing device 10 according to FIG. 1 in a plan view. The wafer 30, which rests on the retaining element 40, and the liner 70, which is arranged at a radial distance from the retaining element 40, can be seen. The rotationally symmetrical construction of the process chamber 20 can also be seen very well in FIG. 2.

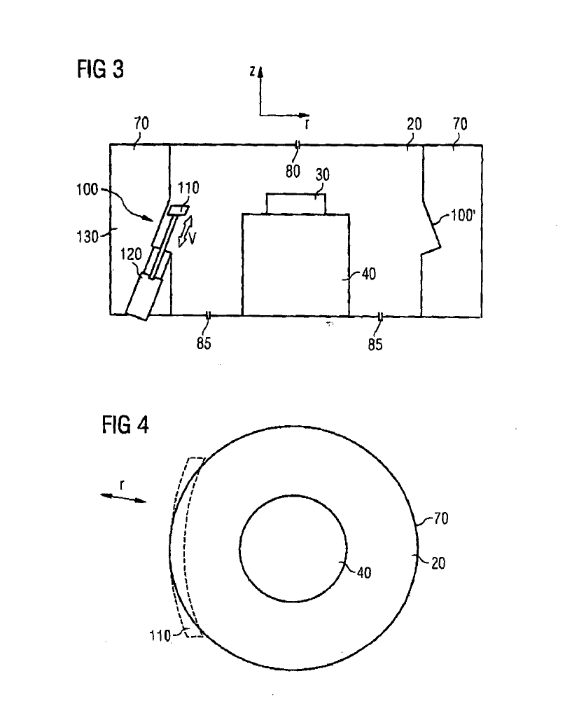

FIG. 3 illustrates a first exemplary embodiment of a plasma processing device 10 according to the invention. Gas inlet openings 80 and gas outlet openings 85 for admitting and drawing off a process gas are schematically indicated and form components for generating the process gas stream. Components for forming plasma are likewise not illustrated for reasons of clarity, they may be arranged inside or outside the process chamber. One gas inlet opening and two gas outlet openings are shown by way of example in FIG. 3, instead of this, numbers of gas inlet openings and gas outlet openings and physical arrangements other than those shown may also be selected.

It can be seen that flow-influencing means 100 which can be used to deliberately disrupt the internal construction of the process chamber 20, which is rotationally symmetrical per se, are arranged in the region of the liner 70 in addition to the components for forming plasma and the components for generating the process gas stream. The flow-influencing means 100 have a diverter plate 110 that can be adjusted using a drive 120 that is illustrated only schematically. The drive 120 may be, for example, an electromechanical or pneumatic drive that can preferably be adjusted continuously or in a plurality of stages and may comprise a bimetal element, a piezoelectric element or an electroactive polymer.

The flow-influencing means 100, or specifically the diverter plate 110, can be used to deliberately influence or disrupt the gas or plasma stream within the process chamber 20. For example, the diverter plate 1 10 can be used to produce asymmetry in the process gas stream within the process chamber 20. Alternatively, the diverter plate 110 can also be used to change the flow behavior of the process gas contained in the process chamber 20 in such a manner that asymmetry, which is present in the process chamber 20 in an undesirable manner, is deliberately compensated for. This is because, despite the greatest care when producing process chamber 20, it is not possible to avoid residual asymmetry remaining in the process chamber 20, which is virtually rotationally symmetrical per se, thus producing an asymmetrical process gas stream within the process chamber 20. If such an asymmetrical flow behavior is present within the rotationally symmetrical process chamber 20, the flow behavior of the process gas can be deliberately compensated for or “rendered symmetrical” by adding further asymmetry using the diverter plate 110; this means that the undesirable asymmetry (present in the process chamber 20) in the flow behavior of the process gas within the process chamber 20 is compensated for by adding further asymmetry.

In the exemplary embodiment according to FIG. 3, the flow-influencing means 100 are arranged in a recess 130 of the liner 70. Alternatively, the flow-influencing means 100 may also be fitted in a passage hole of the liner 70 in such a manner that the flow-influencing means 100 penetrate the liner 70 and are thus connected to the sidewall 60 of the process chamber 20.

In addition to the flow-influencing means 100, additional comparable flow-influencing means may be arranged in the process chamber 20; these are schematically symbolized using a reference symbol 100′.

FIG. 4 again shows the flow-influencing means 100 according to FIG. 3 in a plan view. It can be seen how the diverter plate 110 is pushed into the region between the liner 70 and the retaining element 40 when it is moved along the movement direction V according to FIG. 3. As a result of the diverter plate 110 entering the region between the liner 70 and the retaining element 40, the stream of process gas within the process chamber 20 is influenced to a considerable extent, thus making it possible to produce asymmetry in the flow behavior or, instead of this, to deliberately neutralize or cancel already existing asymmetry in the flow behavior.

FIG. 5 shows a second exemplary embodiment of a plasma processing device 10 according to the invention. A diverter plate 110 that has the shape of a sickle or crescent and belongs to a flow-influencing device 100 that is directly fitted next to or on the retaining element 40 of the plasma processing device 10 can be seen in the plan view in FIG. 5. The diverter plate 110 can be moved both along the Z direction (see FIG. 1) and radially outwards, with the result that the flow behavior of the process gas contained in the process chamber 20 is changed.

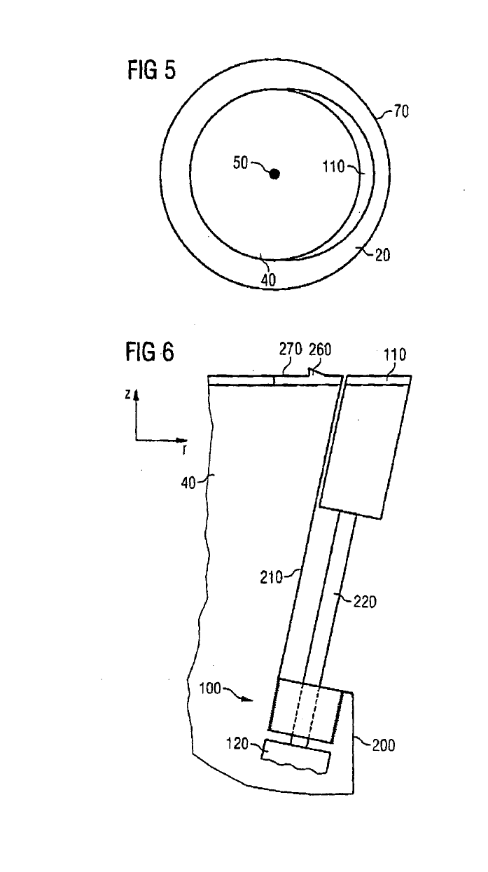

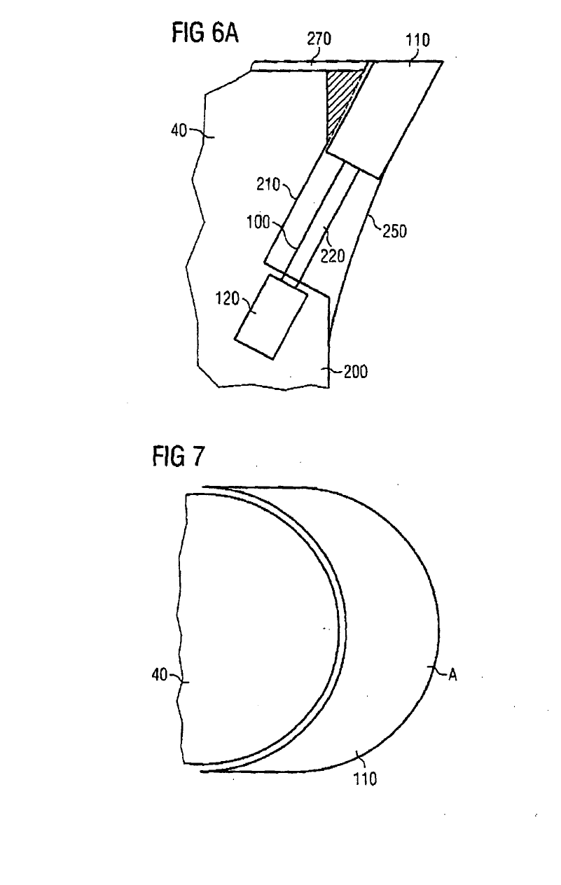

FIG. 6 again illustrates the flow-influencing means 100 according to FIG. 5 in detail in cross-section. The diverter plate 110 and a drive 120, which are connected to the diverter plate 110 and may be, for example, a pneumatic or electromechanical drive that may comprise a bimetal element, a piezoelectric element or an electroactive polymer, can be seen.

FIG. 6 also illustrates how the flow-influencing means 100 are directly integrated on or in the retaining element 40, specifically, the retaining element 40 has, on its sidewall 200, a recess 210 in which the flow-influencing means 100 are mechanically integrated.

FIG. 6 also reveals that the diverter plate 110 can be pushed upwards by displacing a plunger 220 of the drive 120 for the flow-influencing means 100, as a result of which the position of said diverter plate is changed in the radial direction (coordinate direction “r”).

In order to protect the plunger 220 and the drive 120 for the flow-influencing means 100 from the process gas and/or to avoid undesirable swirling of the process gas caused by the plunger 220, the plunger 220 or the entire drive 120 can be covered by a covering element, for example a cover cap 250, such a cover cap 250 may comprise film, for example (for example Kapton® film from DuPont). A suitable cover cap 250 is shown by way of example in FIG. 6a. For the rest, it is also possible, even if this is not explicitly shown in FIGS. 3 and 4 for reasons of clarity, for the drive 120 for the flow-influencing means 100 according to the first exemplary embodiment (see FIGS. 3 and 4), which are fitted in or on the liner 70, to be covered with a suitable cover cap 250.

FIG. 6 also reveals a focus element 260 as part of a focus ring 270 which is placed on the retaining element 40.

FIG. 7 again shows the diverter plate 110 according to FIG. 6 in plan view, to be precise in its “extended” state. It can be seen that the area A of the diverter plate 110 is of a considerable size in relation to the retaining element 40, and is thus capable of considerably changing the flow behavior of the process gas contained in the process chamber 20.

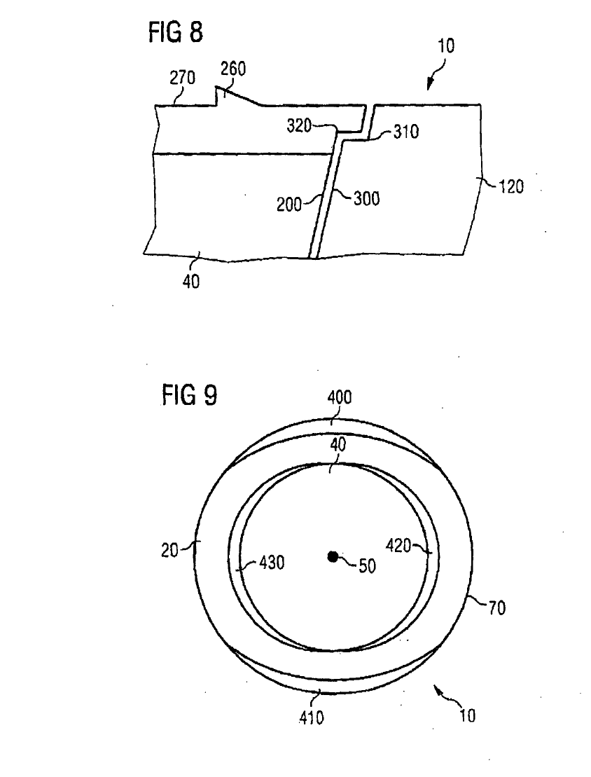

FIG. 8 illustrates a third exemplary embodiment of a plasma processing device according to the invention. The third exemplary embodiment according to FIG. 8 constitutes a variant of the second exemplary embodiment according to FIGS. 5 to 7. Specifically, it can be seen in FIG. 8 that, on its inside 300 that faces the sidewall 200 of the retaining element 40, the contour of the flow-influencing means 100 is adapted to the contour of the sidewall 200 in a very precise manner. Specifically, the inside 300 has, in the region of the diverter plate 110, a step 310 whose profile corresponds to a step 320 in the sidewall 200 of the retaining element 40. As a result of the fact that the contour of the flow-influencing means 100 is adapted to the contour of the sidewall 200 of the retaining element 40 in a largely precise, preferably very precise manner, flow separation can be established in a very specific manner for the flow of the process gas within the process chamber 20 or such flow separation can be prevented by adjusting the diverter plate 110 in a corresponding manner.

FIG. 9 illustrates a plan view of a fourth exemplary embodiment of a plasma processing device according to the invention. It can be seen that the plasma processing device 10 is equipped with flow-influencing means 100 which are arranged both at the edge in the region of the retaining element 40 and at the edge in the region of the liner 70. Specifically, the plasma processing device 10 has two adjustable diverter plates 400 and 410 in the region of the liner 70 and two adjustable diverter plates 420 and 430 in the region of the retaining element 40. The method of operation of the two adjustable diverter plates 400 and 410 corresponds to the method of operation of the diverter plates that has already been explained in connection with FIGS. 3 and 4. The method of operation of the two adjustable diverter plates 420 and 430 corresponds to the method of operation that was explained in connection with the two exemplary embodiments according to FIGS. 5 to 8. The exemplary embodiment according to FIG. 9 thus constitutes a combination of the first three exemplary embodiments.

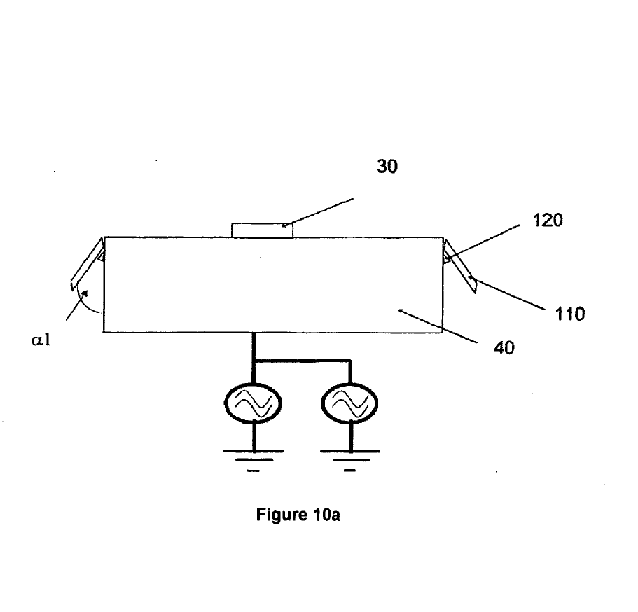

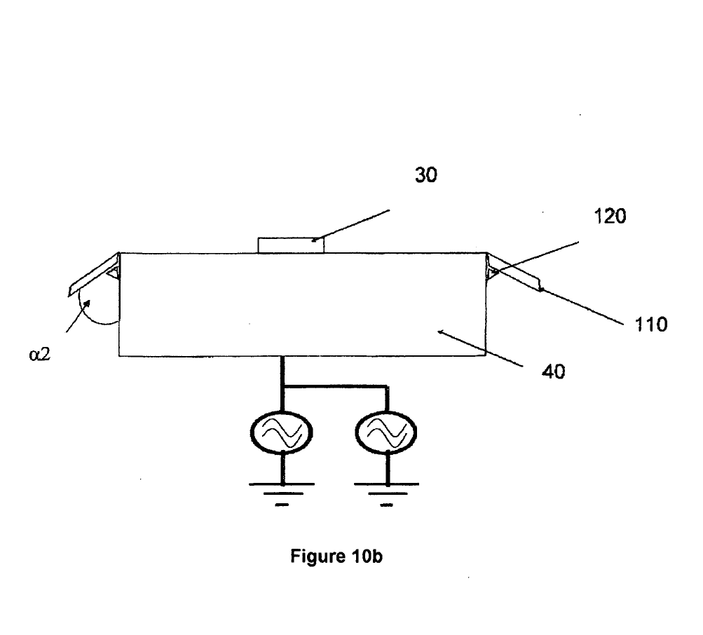

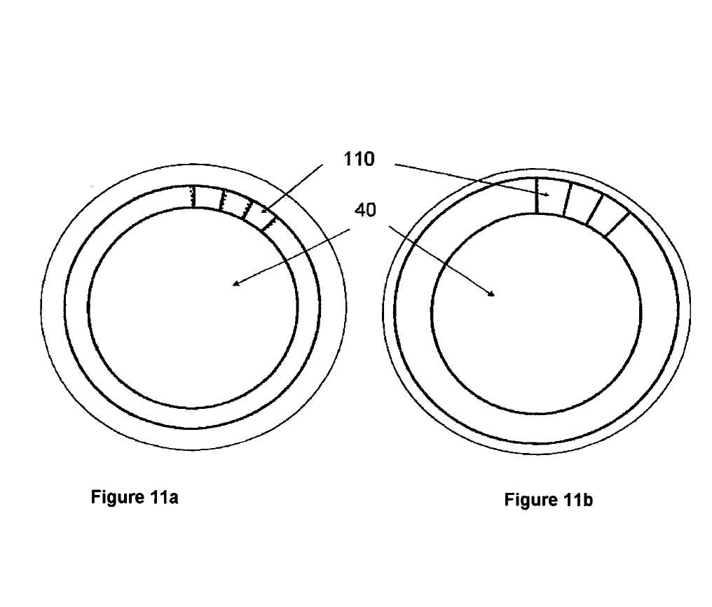

FIG. 10a illustrates a side view of a fifth exemplary embodiment of a plasma processing device 10 according to the invention, which is illustrated in plan view in FIG. 11a. Diverter plates 110 are arranged in the upper region of a retaining element 40 which is circular in plan view and retains a wafer 30. In this case, a multiplicity of diverter plates 110 are fitted over the entire circumference of the retaining means 40 in such a manner that, together with the retaining means 40, they form a circle whose radius can be changed by jointly adjusting the diverter plates 110 using drives 120 which are illustrated only schematically. The diverter plates 110 may also be individually adjusted in order to produce an asymmetrical inner space of the process chamber. While FIGS. 10a and 11a show the diverter plates in a lowered position at an angle α1 with respect to the retaining element 40, the diverter plates 110 in Figures 10b and 11b have been brought into a raised position at an angle α2 with respect to the retaining element 40 using the drives 120. The drives 120 may be, for example, electromechanical or pneumatic drives. The drives can preferably be adjusted continuously or in a plurality of stages and may each comprise a bimetal element, a piezoelectric element or an electroactive polymer. Drives that do not influence the pressure conditions in the process chamber and do not generate any particles are advantageous. It is also advantageous to line the drives with elastic plasma-resistant materials.

Alternatively or additionally, flow-influencing means 100 with adjustable diverter plates may also be arranged in the region of the gas inlet opening 80 shown in FIG. 3 and/or in the region of the gas outlet opening 85 and may operate as an element which changes the cross-section and can be used to asymmetrically adjust the cross-section of the gas inlet opening 80 or the cross-section of the gas outlet opening 85.

What is claimed is:

1. A plasma processing device comprising:
at least one process chamber for receiving an article, in particular a wafer, which is to be processed using a plasma, the process chamber having a prescribed chamber construction; and
a flow-influencing apparatus arranged in the process chamber and set in such a manner that an asymmetrical inner space is produced within the process chamber thereby changing a flow behavior of a process gas contained in the process chamber.

2. The plasma processing device according to claim 1, wherein the process chamber has a symmetrical chamber construction.

3. The plasma processing device according to claim 2, wherein the process chamber has a rotationally symmetrical chamber construction.

4. The plasma processing device according to claim 1, wherein an inside of the process chamber is lined with a liner and the flow-influencing apparatus is arranged in the region of the liner.

5. The plasma processing device according to claim 4, wherein the liner has a recess or a passage opening in which the flow-influencing apparatus is mounted.

6. The plasma processing device according to claim 1, wherein the flow-influencing apparatus directly laterally adjoins a retaining element that is used to retain the article to be processed in the process chamber.

7. The plasma processing device according to claim 1, wherein the flow-influencing apparatus has at least one diverter element that can be adjusted using a drive.

8. The plasma processing device according to claim 7, wherein the diverter element is formed by a diverter plate.

9. The plasma processing device according to claim 7, wherein the diverter element has a cross-sectional area in the shape of a sickle or crescent.

10. The plasma processing device according to claim 7, wherein the drive for the flow-influencing means is pneumatic or electromechanical.

11. The plasma processing device according to claim 10, wherein the drive comprises a bimetal element.

12. The plasma processing device according to claim 10, wherein the drive comprises a piezoelectric element.

13. The plasma processing device according to claim 10, wherein the drive comprises an electroactive polymer.

14. The plasma processing device according to claim 1, wherein the flow-influencing apparatus comprises at least one element that changes the cross-section, is arranged in the vicinity of at least one gas inlet opening and/or at least one gas outlet opening and can be used to asymmetrically adjust the cross-section of the gas inlet opening or the cross-section of the gas outlet opening.

15. The plasma processing device according to claim 1, wherein the article comprises a semiconductor wafer.

16. A method for processing an article using a plasma processing device, the method comprising:
introducing the article into a process chamber of the plasma processing device; and
processing the article using a process gas in the process chamber, wherein flow-influencing devices that are provided in the process chamber are used to produce an asymmetrical inner space within the process chamber and thus to change a flow behavior of a process gas contained in the process chamber.

17. The method according to claim 16, wherein the process chamber has a symmetrical, preferably rotationally symmetrical, chamber construction.

18. The method according to claim 17, wherein the flow-influencing devices are set in a region of a liner or of a process chamber wall in order to change the flow behavior of the process gas.

19. The method according to claim 17, wherein the flow-influencing devices are set in a region of a retaining element that is used to retain the article to be processed in the process chamber.

20. The method according to claim 17, wherein the flow behavior of the process gas is changed using a diverter element having a cross-sectional area in the shape of a sickle or a crescent.

21. The method according to claim 17, wherein, in order to change the flow behavior of the process gas, at least one change in the cross-section of a gas inlet opening and/or a gas outlet opening of the process chamber is produced.
